(19) United States
(12) Patent Application Publication
(10) Pub. No.: US 2019/0207152 A1
(43) Pub. Date: Jul. 4, 2019

(54) OLED PANEL AND METHOD FOR FABRICATING THE SAME

(71) Applicant: SHENZHEN CHINA STAR OPTOELECTRONICS SEMICONDUCTOR DISPLAY TECHNOLOGY CO., LTD., Shenzhen (CN)

(72) Inventors: Zhongguo YANG, Shenzhen (CN); Jinchuan LI, Shenzhen (CN)

(21) Appl. No.: 15/914,157

(22) Filed: Mar. 7, 2018

Related U.S. Application Data
(63) Continuation of application No. PCT/CN2018/073465, filed on Jan. 19, 2018.

(30) Foreign Application Priority Data
Jan. 3, 2018 (CN) 201810005439.1

(51) Int. Cl. H01L 51/52; H01L 51/56; H01L 51/00; B32B 37/00

(52) U.S. Cl. CPC H01L 51/5246; H01L 51/56; H01L 27/3244; B32B 37/0076; H01L 51/0096

(57) ABSTRACT

An OLED panel includes a substrate, a cover plate, an organic light-emitting layer arranged between the substrate and the cover plate, and a glass layer encapsulated on the substrate and ends of the cover plate. The width of the substrate is larger than the width of the cover plate. The glass layer is formed on the surface of the substrate that faces toward the cover plate, and the glass layer wraps the ends of the cover plate to encapsulate the organic light-emitting layer in a space enclosed by the substrate, the cover plate, and the glass layer. A method for fabricating an OLED panel is also provided. Using speed and precision advantages of the three dimensional technology, the present invention prints a glass-packaging material at an outer perimeter of a glass frit encapsulation.

### RELATED APPLICATIONS

The present application is a National Phase of International Application Number PCT/CN2018/073465, filed Jan. 19, 2018, and claims the priority of China Application No. 201810005439.1, filed Jan. 3, 2018.

### FIELD OF THE DISCLOSURE

The disclosure relates to a semiconductor encapsulation technical field, and more particularly to an OLED panel and a method for fabricating the same.

### BACKGROUND

Organic Light-Emitting Diodes, OLEDs for short is feature self-illumination, high brightness, wide view angle, high contrast, flexibility, and low power consumption. Thus, OLEDs have attracted wide publicity. Owning to their display way, OLEDs have gradually replaced the conventional liquid crystal displays. OLEDs are widely applied to screens of mobile phones, displays of computers, and full-color televisions. The display technology of OLEDs is different from the display technology of LCDs. Instead of a backlight module, the display technology of OLEDs uses a very thin coating layer made of an organic material and a glass substrate. When a current flows through the organic material, the organic material will light up. Since an organic material easily reacts with water and oxygen, the demands of packaging OLED displays based on organic material are very strict. In order to commercialize OLED display panels, the related encapsulation technology is greatly researched.

In the conventional technology, the commonly-used liquid glue is sealed in a gap between edges of an upper substrate and a lower substrate. Then, an ultraviolet light is used to solidify the liquid glue to adhere to the two substrates, thereby avoid the infiltration of mist and oxygen. However, the adhering way is not ideal. At a high temperature or after long-term use, the encapsulated glue easily ages or falls off, so as to fail the whole encapsulated structure and affect internal optical components.

### SUMMARY

A technical problem to be solved by the disclosure is to provide an OLED panel and a method for fabricating the same, which guarantees the good encapsulated effect of the OLED panel at a high temperature or after long-term use.

An objective of the disclosure is achieved by following embodiments.

An OLED panel comprises a substrate, a cover plate, an organic light-emitting layer arranged between the substrate and the cover plate, and a glass layer encapsulated on the substrate and ends of the cover plate, a width of the substrate is larger than a width of the cover plate, the glass layer is formed on a surface of the substrate that faces toward the cover plate, and the glass layer wraps the ends of the cover plate to encapsulate the organic light-emitting layer in a space enclosed by the substrate, the cover plate, and the glass layer.

In an embodiment, at least one part of the glass layer covers a surface of the cover plate far away the substrate.

In an embodiment, the glass layer is formed on the surface of the substrate layer by layer by three-dimensional printing.

In an embodiment, a thickness of an edge of the cover plate is less than a thickness of a middle of the cover plate whereby a step-like recess portion is formed on the surface away from the substrate, and the glass layer fills the step-like recess portion.

In an embodiment, a surface of the glass layer is flush with the substrate.

In an embodiment, a bottom surface of the recess portion is provided with a first groove, and the glass layer fills the first groove.

In an embodiment, the OLED panel further comprises an interval encapsulating layer made of a sintered glass frit encapsulated between the substrate and the cover plate, and the interval encapsulating layer encapsulates the organic light-emitting layer.

In an embodiment, an inner wall of the interval encapsulating layer is laminated to the glass layer.

A method for fabricating an OLED panel is provided. The method comprises: providing a substrate and a cover plate; forming a circle of a groove on a lower surface of the cover plate; coating a circle of a glass frit on an upper surface of the cover plate and burning out an organic material within the glass frit; forming an organic light-emitting layer on an upper surface of the substrate; laminating the cover plate to the substrate in an vacuum environment, such that the glass frit encloses the organic light-emitting layer, and using a laser to sinter the glass frit; cutting the cover plate within the groove; and forming a glass-melting material on the surface of the substrate to fill the groove.

In an embodiment, the glass-melting material is gradually printed on the surface of the substrate from bottom to top in a layer-by-layer manner by a three-dimensional printer, until the glass-melting material fills the groove.

Using speed and precision advantages of the three dimensional technology, the present invention prints a glass-packaging material at an outer perimeter of a glass frit encapsulation. Since the glass-packaging material is printed in a layer-by-layer manner after melting glass, the compactness of the glass-packaging material is better than that of a glass frit, lest an organic material of the glass frit be sintered to form pores and cracks that moisture enters, thereby achieving the more reliable encapsulation effect.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a structural schematic view of an OLED panel according to an embodiment 1 of the disclosure;

FIG. 2 is a structural schematic view of a part of an OLED panel according to an embodiment 1 of the disclosure;

FIG. 3 is a flowchart of fabricating an OLED panel according to an embodiment 1 of the disclosure;

FIG. 4 is a structural schematic view of fabricating an OLED panel according to an embodiment 1 of the disclosure;

FIG. 5 is a structural schematic view of an OLED panel according to an embodiment 2 of the disclosure; and

FIG. 6 is a structural schematic view of a part of an OLED panel according to an embodiment 2 of the disclosure.

### DETAILED DESCRIPTION OF PREFERRED EMBODIMENTS

In order to understand the above objectives, features and advantages of the present disclosure more dearly, the present disclosure is described in detail below with references to the accompanying drawings and specific embodiments. The present disclosure is only to exemplify the present invention but not to limit the scope of the present invention.

### Embodiment 1

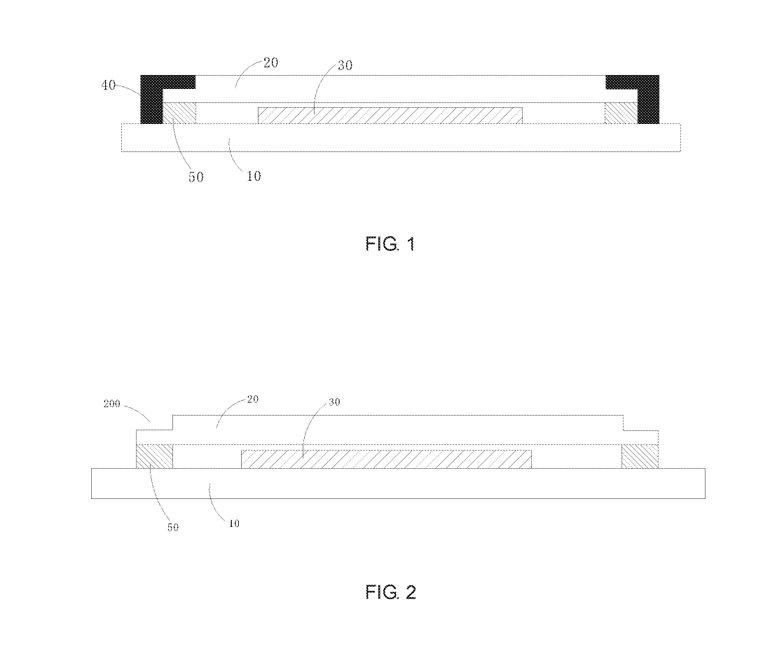

Refer to FIG. 1. According to an embodiment of the present invention, an OLED panel comprises a substrate 10, a cover plate 20, an organic light-emitting layer 30 arranged between the substrate 10 and the cover plate 20, and a glass layer 40 encapsulated between the substrate 10 and ends of the cover plate 20. The width of the substrate 10 is larger than the width of the cover plate 20. The glass layer 40 is formed on a surface of the substrate 10 that faces toward the cover plate 20. The glass layer 40 covers the ends of the cover plate 20 to encapsulate the organic light-emitting layer 30 in a space enclosed by the substrate 10, the cover plate 20, and the glass layer 40. The substrate 10 is a thin film transistor (TFT) substrate and the cover plate 20 is a glass cover plate.

The glass layer 40 is gradually formed on the surface of the substrate 10 by three-dimensional printing, until at least one part of the glass layer 40 covers a surface of the cover plate 20 far away the substrate 10. As shown in FIG. 2, a thickness of an edge of the surface of the cover plate 20 far away the substrate 10 is less than a thickness of a middle of the surface of the cover plate 20 far away the substrate 10 whereby a step-like recess portion 200 is formed. The glass layer 40 fills the step-like recess portion 200, which guarantees that the printed glass layer 40 and the cover plate 20 have a larger combined area and the better combined strength. After printing the glass layer 40, an upper surface of the glass layer 40 is level with the substrate 10. Thereby, the affection on the appearance and the display effect is most greatly reduced.

An interval encapsulating layer 50 made of a sintered glass frit is encapsulated between the substrate 10 and the cover plate 20, and the glass frit encloses the organic light-emitting layer 30. An inner wall of the interval encapsulating layer 50 is laminated to the glass layer 40.

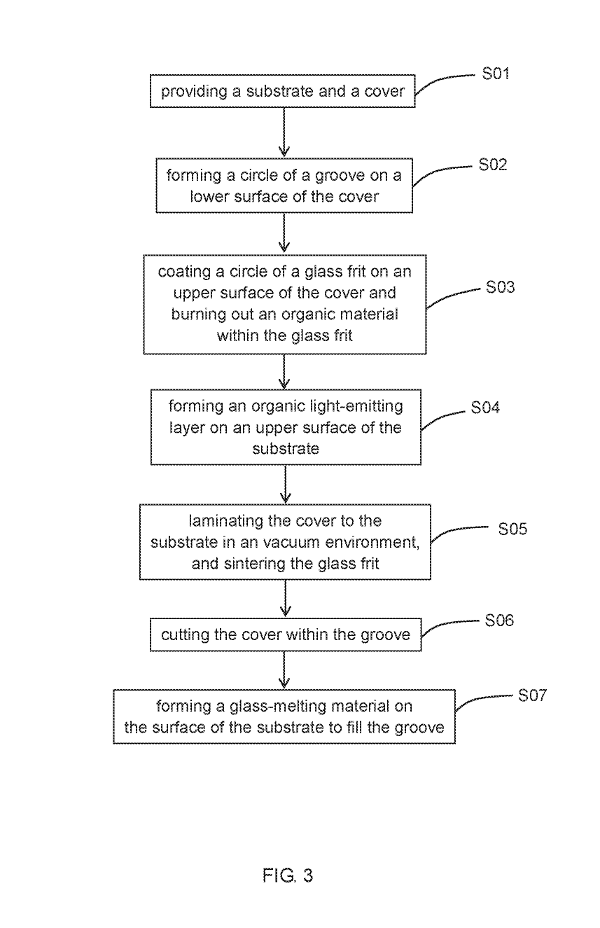

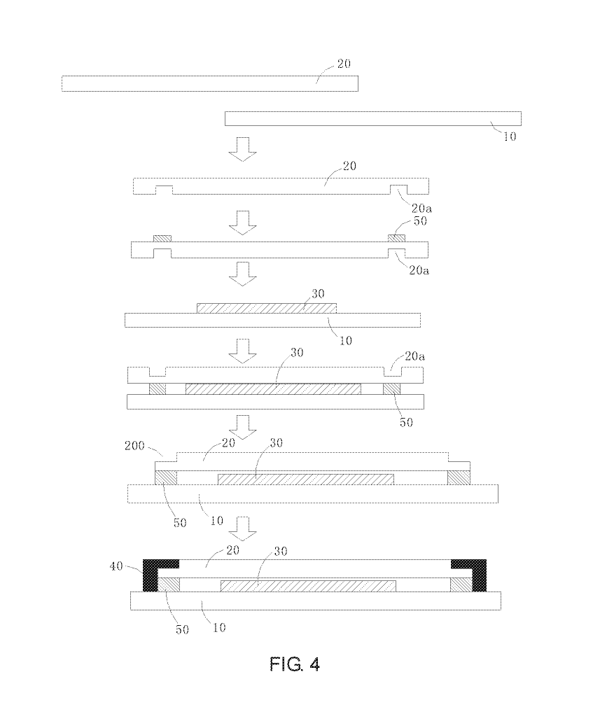

As shown in FIG. 3 and FIG. 4, the present invention provides a method for fabricating an OLED panel, which comprises:

S01: providing a substrate 10 and a cover plate 20;

S02: forming a circle of a groove 20a on an edge of a lower surface of the cover plate 20 and forming a cutting line in the groove 20a by cutting;

S03: coating a circle of a glass frit on an upper surface of the cover plate 20 and burning out an organic material within the glass frit in an oven;

S04: forming an organic light-emitting layer 30 on an upper surface of the substrate 10;

S05: laminating the cover plate 20 to the substrate 10 in an vacuum environment, such that the glass frit encloses the organic light-emitting layer 30 and sintering the glass frit, wherein an upper surface and a lower surface of the glass frit respectively adhere to inner surfaces of the cover plate 20 and the substrate 10, and the sintering way may be a contactless sintering way using a laser, whereby a local sintering treatment is more precisely performed;

S06: cutting the cover plate 20 within the groove 20a, wherein removing the redundant glass substrate outside the cutting line recited in S02 as a cutting boundary;

S07: forming a glass-melting material at an outer perimeter of the glass frit on the substrate 10 by a three-dimensional printer and using the glass-melting material to fill the groove 20a. When the three-dimensional printer is used to form the glass-melting material, the glass-melting material is printed on the surface of the substrate 10 from bottom to top in a layer-by-layer manner, until the glass-melting material fills the groove 20a and is level with the substrate 10. Furthermore, the height of the groove 20a is half of the thickness of the cover plate 20. The widths of the glass-melting materials printed in the groove 20a and on the substrate 10 are equal to each other, which preferably adapts to the three-dimensional printing technology, improves the adhesion of the printed glass and either of the cover plate 20 and the substrate 10, and enhance the encapsulation effect.

### Embodiment 2

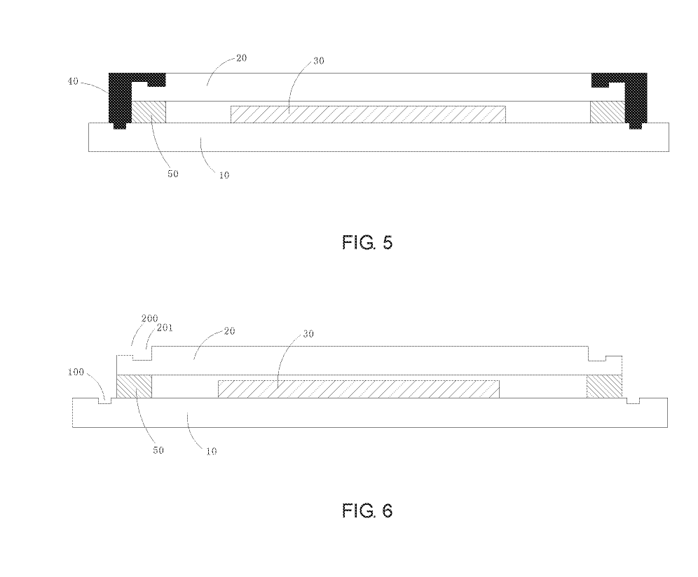

As shown in FIG. 5 and FIG. 6, based on embodiment 1, the bottom surface of the recess portion 200 of the edge of the upper surface of the cover plate 20 is further provided with a circle of a first groove 201. The surface of the substrate 10 that faces toward the cover plate 20 is also provided with a circle of a second groove 100. The glass layer 40 fills the first groove 201 and the second groove 100. The glass-melting material is formed in the first groove 201 to improve the combined strength between the glass layer 40 and the substrate 10. The second groove 100 and the interval encapsulating layer 50 made of the sintered glass frit have a height difference, such that the external glass layer 40 is more easily encapsulated at the outer perimeter of the interval encapsulating layer 50, thereby improving the combined effect of the printed glass-melting layer and the substrate 10.

In conclusion, since the organic material of the glass frit of the interval encapsulating structure cannot be completely volatilized in an oven, many pores and cracks within the glass frit appear after using a laser to sinter the glass frit. The pores and the cracks are used as invading channels for moisture to reduce the encapsulating effect. Therefore, using the three-dimensional technology, the present invention forms a circle of the glass layer 40 that encloses the glass frit. The present invention has incomparable advantages in printing speed and precision to achieve the near-perfect effect of three-dimensional printing.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. An OLED panel, comprising a substrate, a cover plate, an organic light-emitting layer arranged between the substrate and the cover plate, and a glass layer encapsulated between the substrate and ends of the cover plate, a width of the substrate is larger than a width of the cover plate, the glass layer is formed on a surface of the substrate facing toward the cover plate, and the glass layer wrapping the ends of the cover plate to encapsulate the organic light-emitting layer in a space enclosed by the substrate, the cover plate, and the glass layer.

2. The OLED panel according to claim 1, wherein at least part of the glass layer covers a surface away from the substrate of the cover plate.

3. The OLED panel according to claim 2, wherein the glass layer is formed on the surface of the substrate layer by layer by three-dimensional printing.

4. The OLED panel according to claim 3, wherein a thickness of an edge of the cover plate is less than a thickness of a middle of the cover plate whereby a step-like recess portion is formed on the surface away from the substrate, and the glass layer fills the step-like recess portion.

5. The OLED panel according to claim 4, wherein a surface of the glass layer is flush with the substrate.

6. The OLED panel according to claim 4, wherein a bottom surface of the recess portion is provided with a first groove, and the glass layer fills the first groove.

7. The OLED panel according to claim 1, further comprising an interval encapsulating layer made of a sintered glass frit encapsulated between the substrate and the cover plate, and the interval encapsulating layer encapsulates the organic light-emitting layer.

8. The OLED panel according to claim 7, wherein an inner wall of the interval encapsulating layer is laminated to the glass layer.

9. The OLED panel according to claim 2, further comprising an interval encapsulating layer made of a sintered glass frit encapsulated between the substrate and the cover plate, and the interval encapsulating layer encapsulates the organic light-emitting layer.

10. The OLED panel according to claim 9, wherein an inner wall of the interval encapsulating layer is laminated to the glass layer.

11. The OLED panel according to claim 3, further comprising an interval encapsulating layer made of a sintered glass frit encapsulated between the substrate and the cover plate, and the glass frit encapsulates the organic light-emitting layer therein.

12. The OLED panel according to claim 11, wherein an inner wall of the interval encapsulating layer is laminated to the glass layer.

13. The OLED panel according to claim 4, further comprising an interval encapsulating layer made of a sintered glass frit encapsulated between the substrate and the cover plate, and the glass frit encapsulates the organic light-emitting layer therein.

14. The OLED panel according to claim 13, wherein an inner wall of the interval encapsulating layer is laminated to the glass layer.

15. The OLED panel according to claim 5, further comprising an interval encapsulating layer made of a sintered glass frit encapsulated between the substrate and the cover plate, and the glass frit encapsulates the organic light-emitting layer therein.

16. The OLED panel according to claim 15, wherein an inner wall of the interval encapsulating layer is laminated to the glass layer.

17. The OLED panel according to claim 6, further comprising an interval encapsulating layer made of a sintered glass frit encapsulated between the substrate and the cover plate, and the glass frit encapsulates the organic light-emitting layer therein.

18. The OLED panel according to claim 17, wherein an inner wall of the interval encapsulating layer is laminated to the glass layer.

19. A method for fabricating an OLED panel, comprising:
providing a substrate and a cover plate;
forming a circle of a groove on a lower surface of the cover plate;
coating a circle of a glass frit on an upper surface of the cover plate and burning out an organic material within the glass frit;
forming an organic light-emitting layer on an upper surface of the substrate;
laminating the cover plate to the substrate in a vacuum environment, such that the glass frit encloses the organic light-emitting layer, and using a laser to sinter the glass frit;
cutting the cover plate within the groove; and
forming a glass-melting material on the surface of the substrate to fill the groove.

20. The method for fabricating the OLED panel according to claim 19, wherein the glass-melting material is printed on the surface of the substrate from bottom to top in a layer-by-layer manner by a three-dimensional printer, until the glass-melting material fills the groove.
